(19) United States
(12) Patent Application Publication
(10) Pub. No.: US 2010/0193768 A1
(43) Pub. Date: Aug. 5, 2010

(54) SEMICONDUCTING NANOWIRE ARRAYS FOR PHOTOVOLTAIC APPLICATIONS

(75) Inventor: Youssef Habib, Lancaster, PA (US)

Correspondence Address: TED SABETY, c/o Sabety +associates, PLLC, 1130 Bedford Rd., PLEASANTVILLE, NY, 10570, US

(73) Assignee: ILLUMINEX CORPORATION, Lancaster, PA (US)

(21) Appl. No.: 12/759,537

(22) Filed: Apr. 13, 2010

Related U.S. Application Data
(63) Continuation-in-part of application No. 12/185,773, filed on Aug. 4, 2008.
Application No. 12/185,773 is a continuation-in-part of application No. 11/917,505, filed on Jul. 16, 2008.
(60) Provisional application No. 61/169,279, filed on Apr. 14, 2009.
(60) Provisional application No. 61/177,265, filed on May 11, 2009.
(60) Provisional application No. 61/242,212, filed on Sep. 14, 2009.
(60) Provisional application No. 60/692,202, filed on Jun. 20, 2005.

(51) Int. Cl. H01L 29/06; H01L 21/20

(52) U.S. Cl. 257/9; 438/478; 977/762; 257/E21.09; 257/461; 438/63; 257/E29.024; 257/431

(57) ABSTRACT

This invention relates to the fabrication of nanowires for electrical and electronic applications. A method of growing silicon nanowires using an alumina template is disclosed whereby the aluminum forming the alumina is also used as the catalyst for growing the silicon nanowires in a VLS (CVD) process and as the semiconductor dopant. In addition, various techniques for masking off parts of the aluminum and alumina in order to maintain electrical isolation between device layers is disclosed.

### PRIORITY CLAIM

This patent application hereby incorporates by reference and claims priority as a continuation in part to U.S. patent application Ser. Nos. 12/185,773 filed on Aug. 4, 2008, 11/917,505 filed on Dec. 14, 2007, the U.S. National Stage of PCT/US06/023662 filed on Jun. 16, 2006, with priority to 60/692,202 filed on Jun. 17, 2005 and as a continuation to U.S. Pat. App. Nos. 61/169,279 filed on Apr. 14, 2009, 61/177,265 filed on May 11, 2009 and 61/242,212 filed on Sep. 14, 2009, all of which are incorporated herein by reference.

### GOVERNMENT LICENSE RIGHTS

The U.S. Government has a paid-up license in this invention and the right in limited circumstances to require the patent owner to license others on reasonable terms as provided for by the terms of Contract No. DOE-DE-FG02-07ER86313 awarded by The Department of Energy.

### SUMMARY OF THE INVENTION

Single crystal or polycrystalline silicon solar cells are currently the dominant commercial photovoltaic (PV) technologies, comprising greater than 90% of the commercial market. Through advances in device design, crystalline silicon solar cells have reached module efficiencies in the range of 16-20%. While efforts are on-going to push cell efficiencies closer to the theoretical limit of 31% for a single bandgap silicon solar conversion device, high module cost impedes market acceptance of this clean, alternative approach to electrical power generation, largely due to the production costs of the silicon wafers used to manufacture the photovoltaic modules. Currently, solar electricity generation is the source of less than 0.1% of the U.S. energy supply. New technologies that bring down the per-watt cost of PV electricity while making it more readily accessible to consumers are required to realize the potential of this clean, abundant source of electricity.

The unique approach to PV device engineering disclosed here circumvents the need for high purity silicon wafers by utilizing a radial p-n junction nanowire (NW) array geometry. The nanowire approach reduces the amount of silicon utilized to the essential amount needed to comprise the active photo-conversion nano-structural components. The radial junctions utilize both the narrow diameter of NWs to improve carrier collection and the high aspect ratio of the structures to enhance light absorption. In radial p-n junctions, the direction of light absorption is decoupled from that of carrier collection by making the two relevant dimensions orthogonal. The NWs are optically thick along the long axis, which maximizes the light absorption, but they are thin in the radial direction, thus creating a short photo-generated carrier extraction distance. These geometrical attributes increase device efficiency compared to planar structures. The NWs typically have a p-type crystalline silicon core that is coated with an n-type shell, and they can be made as p-n or p-i-n junctions as desired, where the i is intrinsic silicon.

Techniques for the bottom-up fabrication of single-crystal semiconductor nanowire arrays enable low cost production methods for the fabrication of crystalline Si solar cells. The silicon nanowire (SiNW) growth process, known as vapor-liquid-solid (VLS) growth, involves the use of metal nano-particles to catalyze SiNW growth from a vapor phase ambient. Similar VLS methods can also be used to grow silicon, germanium (Ge), gallium antimonide (GaSb), gallium nitride (GaN) or other semiconducting NWs for PV or other device applications. An interesting aspect of using NW arrays produced by the VLS process for solar cell applications is the ability to obtain single-crystal semiconductor NWs on low-cost, non-crystalline substrates such as glass or metal foils at high growth rates (1-10 microns/minute) and reduced temperatures (400-600° C.) with minimal to no post-growth processing. This offers the potential for significant energy and materials savings in manufacturing that lead to reduced fabrication costs compared to silicon wafer based approaches.

Gold seeds are typically used for VLS growth of silicon nanowires, primarily due to the low Au—Si eutectic temperature (363° C.) and favorable wetting properties, which result in the formation of a stable liquid alloy phase at the nanowire tip. However, Au is incorporated into the lattice of the SiNWs during VLS growth at concentrations as high as 5×10¹⁷-1.5×10¹⁸ cm⁻³, forming deep level electronic states within the bandgap of Si which degrades the charge-carrier lifetime by acting as centers for recombination. However, Aluminum may be used as a catalyst in VLS processes instead.

Aluminum is routinely used in Si process lines and thus makes a very attractive material for catalyzing SiNWs. The incorporation of Al into the Si lattice creates states close to the Si valence band, and hence, is an appropriate p-type dopant for semiconductor applications such as PV devices. The Al—Si phase diagram is similar to Au—Si, forming a fairly low temperature eutectic (577° C.), making Al a suitable catalyst for VLS growth of SiNWs for PV device applications. Further, a vapor-solid-solid phase can similarly be used to produce SiNWs at temperatures lower than 500° C. using a vapor phase Si precursor. Processing techniques that eliminate the catalyst seeding process, work with low cost materials, and require minimal processing steps, are the path to realizing cost-effective manufacturing of NW devices and all of the associated benefits.

One embodiment of the invention involves partially anodizing a layer of Al metal to form a nano-porous anodic aluminum oxide (AAO) layer on an Al metal surface or other conductive substrate coated with aluminum, and subsequently using the VLS technique to catalyze the axial growth of high aspect ratio SiNWs from a vapor-phase ambient containing silane (SiH₄) or other Si containing (Si₂H₆, SiCl₄ etc.) gas, by using the underlying Al metal as the catalyst. Al metal substrates can be used as a starting material, or, Al can be applied as a layer or coating to another substrate material. The SiNWs grown by this process nucleate at the Al-AAO interface, via the formation of an Al—Si eutectic phase at the base of the nano-pores, and grow up and out of the AAO pores, extending into free-space. The SiNWs contain a volumetric concentration of 10¹⁸/cm³ to 10²⁰/cm³ Al atoms that act as an effective p-type dopant, eliminating the need to add additional dopant gas sources during SiNW growth. When properly engineered AAO/Al substrates are used, the NWs are in Ohmic contact with the Al metal, the anode of the PV device. A conformal layer of n-type Si is subsequently deposited, preferably epitaxially in-situ, creating a multitude of p-n diode junctions. In the preferred embodiment, the n-type layer is deposited without the device being removed from the reactor vessel. A thin p-type layer can be formed covering the entire AAO surface prior to n-type coating to maximize the junction area and provide electrical continuity to the diode area. This additional layer can also insulate the N layer from the substrate by filling any pores in the AAO that for some reason do not have silicon nanowires occupying them. As desired, a layer of intrinsic material can be applied between the p and n layers to form p-i-n diodes or as a continuous layer between discrete p (n)-type nanowires and the subsequent continuous n (p)-type coating. The porous AAO layer is multifunctional in that it serves as a template, controlling the diameter and spacing of the SiNWs, and as an insulator that isolates the n-type layer from the Al substrate. A transparent conductive coating is deposited over the n-type Si layer, forming the cathode. Thus, a single material, Al: provides the catalyst for SiNW growth, a PV electrode (anode), p-type SiNW dopant source, insulating layer in the form of porous AAO, NW template (AAO), and the mechanical supporting structure of the device.

This process for the versatile production of SiNWs enables a new generation of solar electric devices that are lightweight, versatile, low-cost, and posses novel design attributes. Nano-PV electricity generation using readily produced, diverse implementations can be realized including: conformal fitting Al foils or applied Al layers for PV coatings on the bodies of electric cars, spools of SiNW-on-Al threads for PV textile applications, or simply Al deposited on glass panels or other insulating substrates to compete head-to-head with the established and dominant Si wafer-based PV device market.

### BRIEF DESCRIPTION OF THE DRAWINGS

FIG. 1: Schematic of a SiNW PV device concept showing the Al core, p-type SiNWs, attached to the Al, growing through an insulating AAO sheath that are coated with a continuous n-type Si layer. The n-type layer is coated with an outer conductive electrode (cathode) opposite to the Al core electrode (anode). The AAO provides electrical insulation between the anode and cathode.

FIG. 2: This schematic shows a cross-section of a porous anodic aluminum oxide film on Al metal.

FIG. 3: SEM micrographs showing a porous AAO layer produced on the surface of an Al wire at increasing levels of magnification.

FIG. 4. Schematic representation of the anodization process. (a) An as formed AAO nanopore anodized at high voltage. (b) Continued step-down anodization at lowered voltages creates nanofingers at the channel bottom. (c) Phosphoric acid etch solution widens the pore to the desired diameter while thinning the anodized layer at the bottom of the pore.

FIG. 5: SEM micrograph showing a low cost, effective substrate for SiNW growth.

FIG. 6: SiNW's grown on partially anodized Al on a glass substrate showing the entire Glass/Al/AAO and SiNW structures (left, 30 min. growth), an intermediate magnification image of the interface (center, 5 min. growth) and a high magnification image (right, 5 min.) showing details of the Glass/Al/AAO/SiNW interface.

FIG. 7: Versatile SiNW PV device architectures on glass (left) for rigid, planar devices and on bulk Aluminum (right) for conformal structures.

FIG. 8: SEM Image of AAO an Al metal showing the barrier layer.

FIG. 9: Aluminum anodized in (left to right) oxalic, malonic, and tartaric acid.

FIG. 10: Schematic of the anodization cell used for growing a porous alumina template about the periphery of a thread. Schematic on right shows the uniform electric field pattern that will ensure a uniform porous layer growth.

FIG. 11: High magnification SEM images (100 kX) showing nanowire tips with (left) and without (right) obvious remnant Al catalytic material on the tip.

FIG. 12: AAO on Al metal before (left), and after (right) step down and pore widening.

FIG. 13: (a) Low magnification TEM image of radial p-n Si nanowire showing uniform coating thickness along nanowire axis; (b) High magnification TEM image of radial p-n Si nanowire showing crystalline p-Si core and polycrystalline n-Si shell layer.

FIG. 14: SEM micrograph of non-porous aluminum oxide that can be produced in areas of an Al substrate (or other substrate with an Al coating) where nanowire growth is undesirable. The nanowires will not nucleate through the non-porous oxide.

FIG. 15: Process schematic for PV thread manufacture.

FIG. 16: Current-Voltage schedule used for the “Step-Down” anodization process.

FIG. 17: Porous AAO on Al thread before (left) and after (right) Pore widening after using the anodization schedule in FIG. 18.

FIG. 18: Shows an alternate “Step Down” anodization procedure and the resulting AAO on the surface of an Al thread.

FIG. 19: Shows diagrammatically the steps of the method of fabrication.

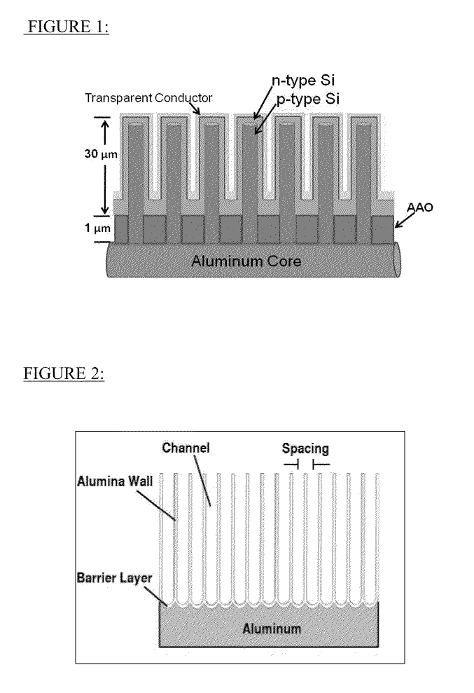

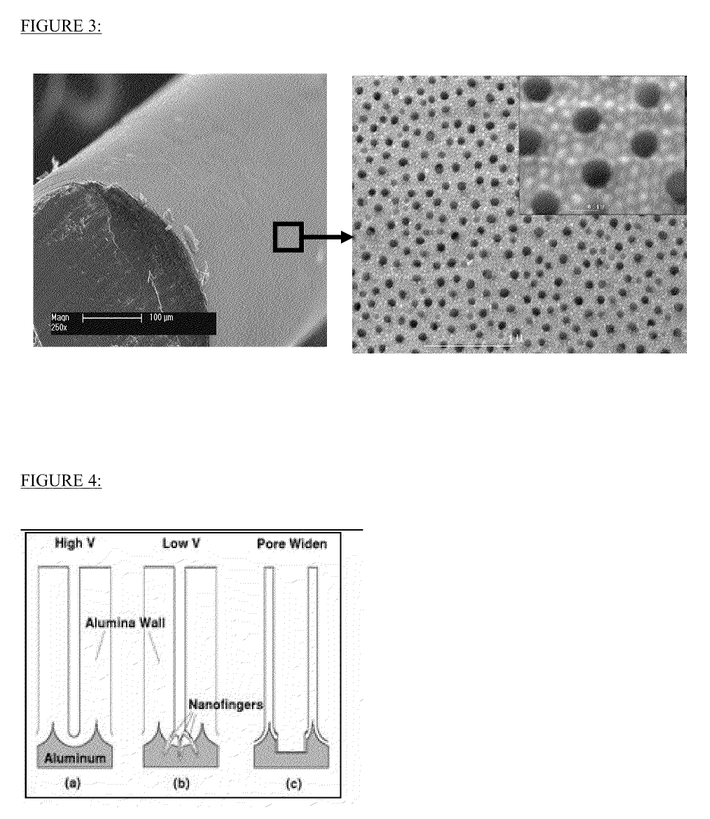

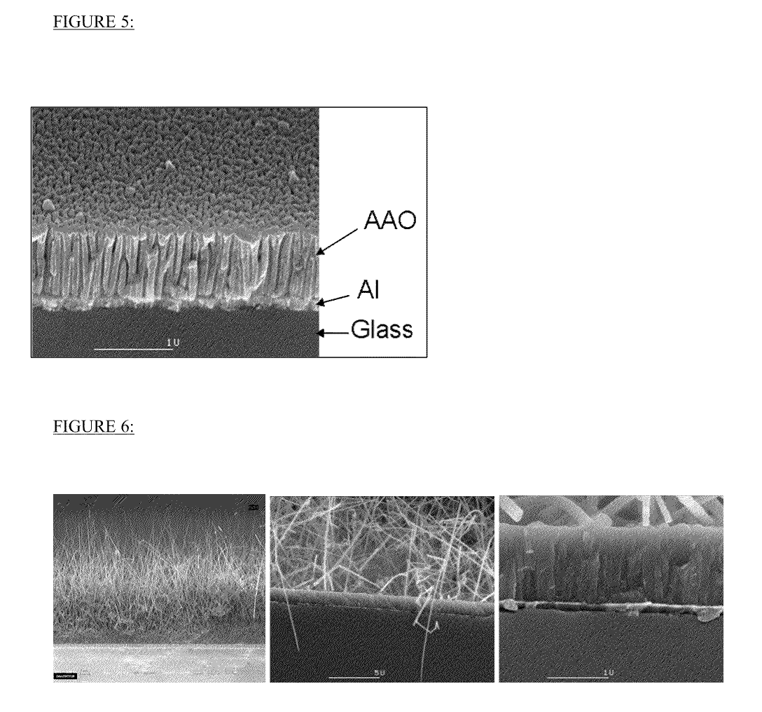

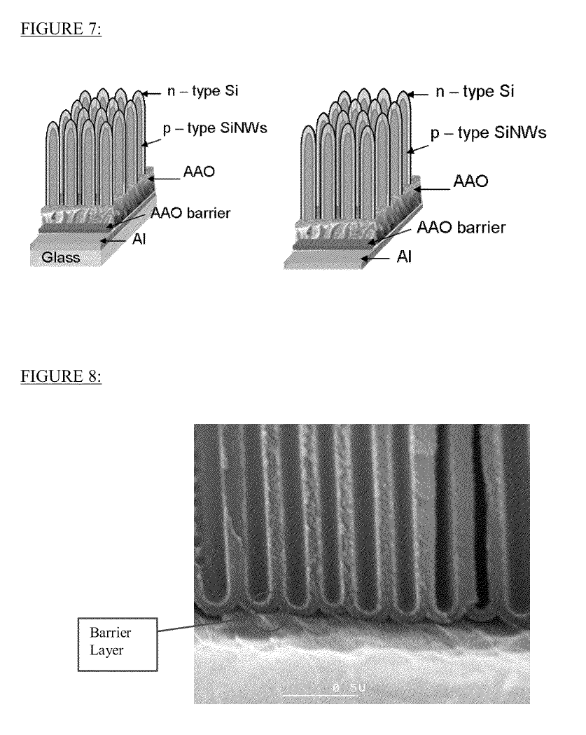

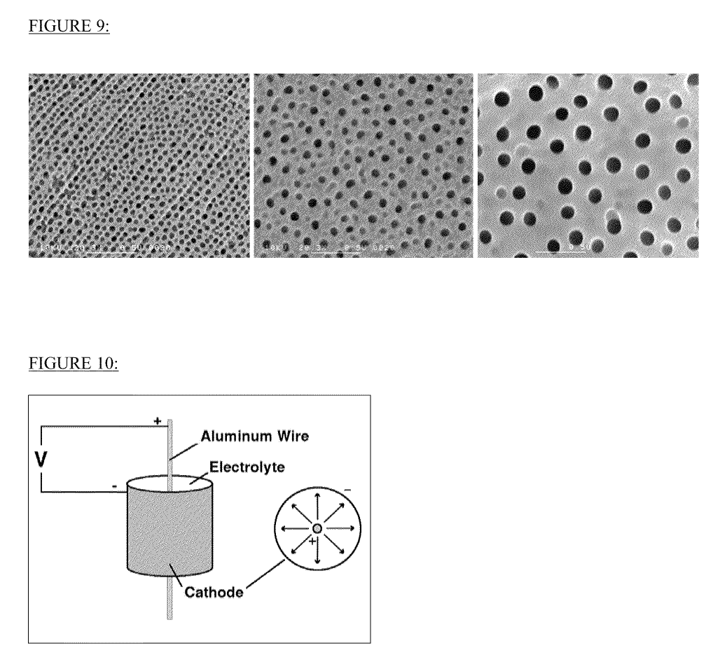

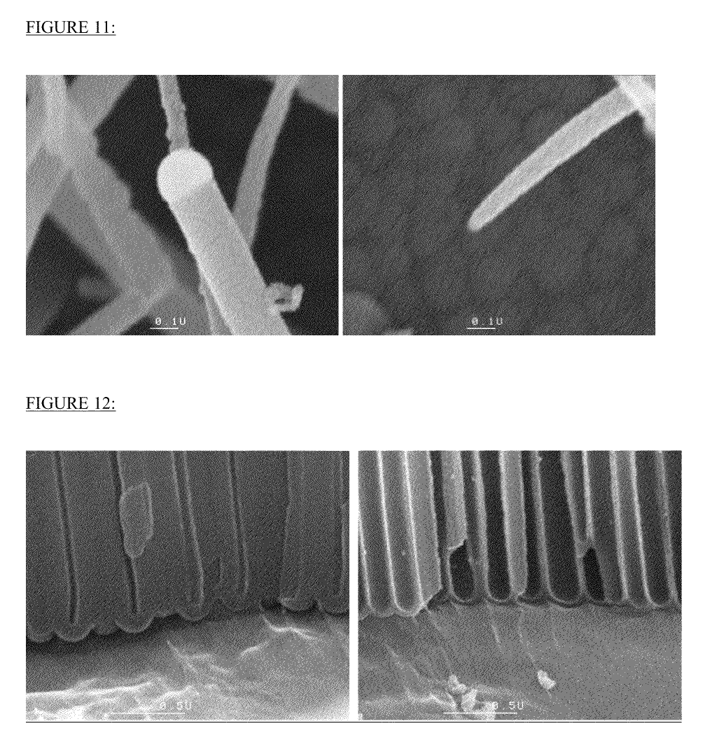

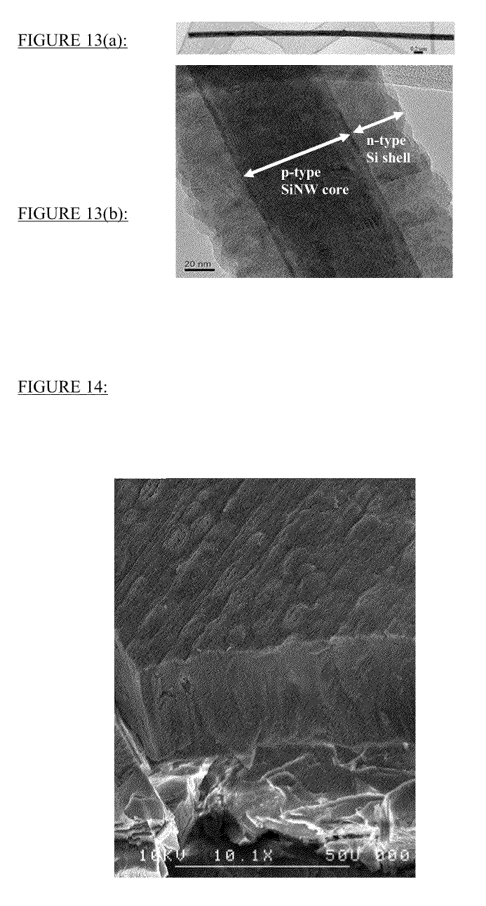

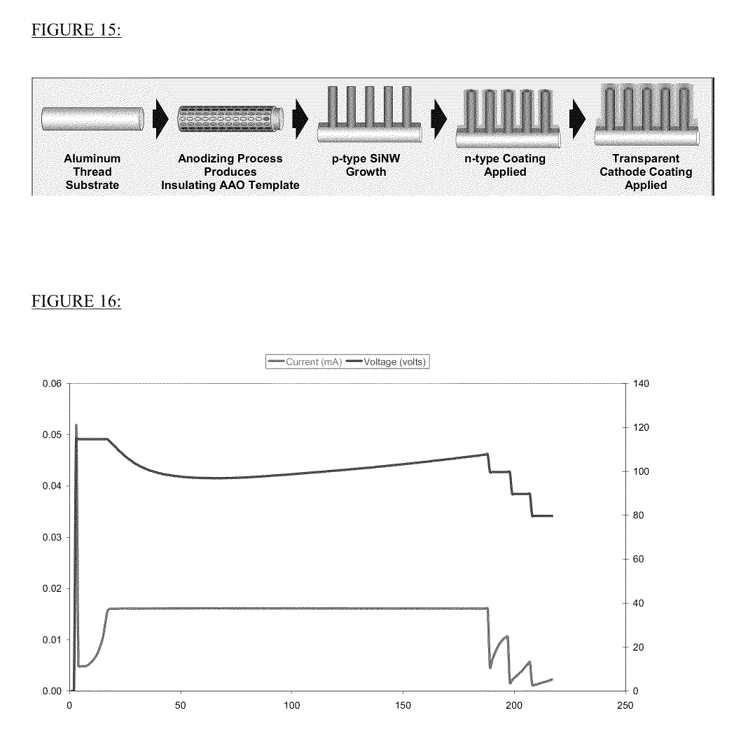

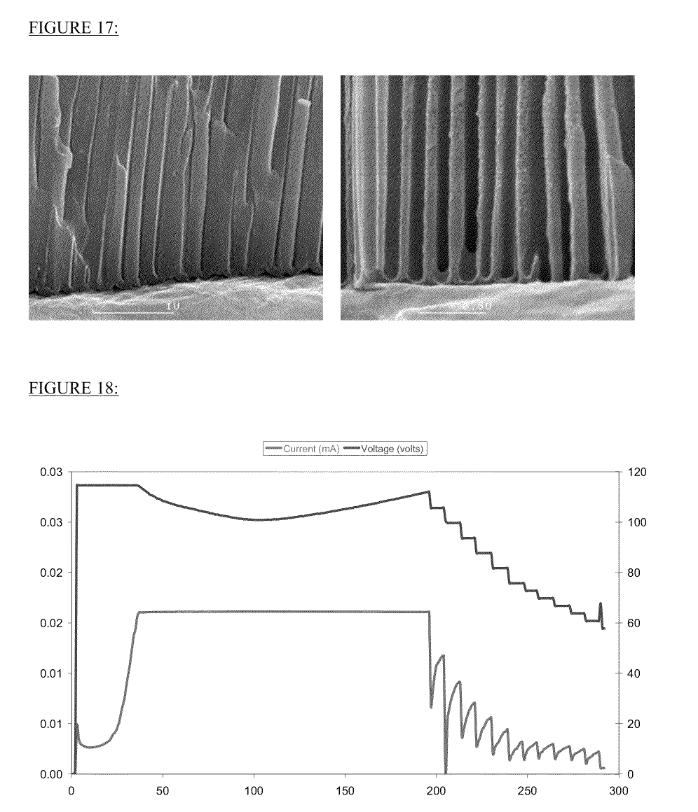

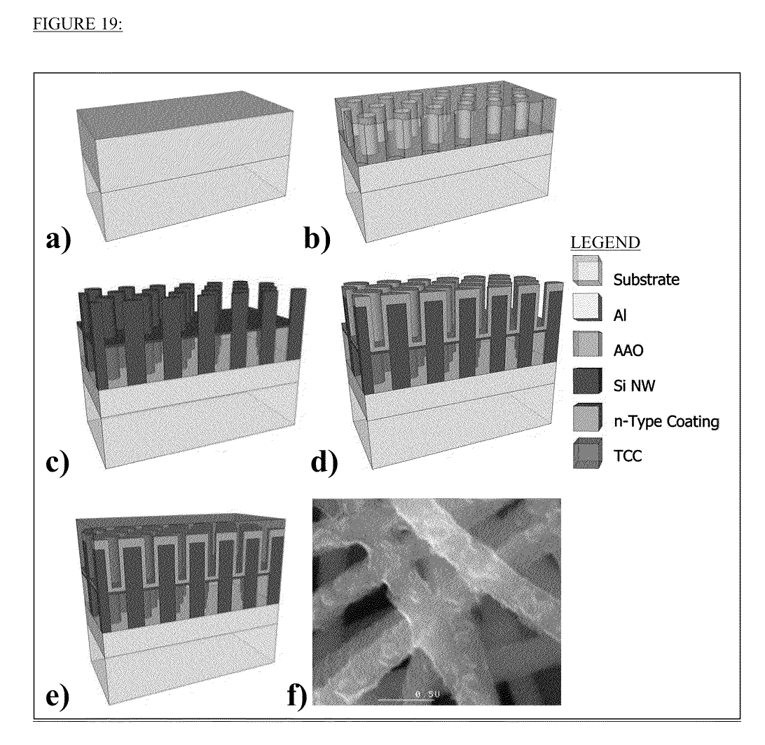

### DETAILED DESCRIPTION OF THE PREFERRED EMBODIMENTS

This invention relates to the growth and use of nanowires on substrates in order to produce electrical circuits, including photovoltaic devices.

The present patent encompasses both the design of SiNW array based PV devices including components that comprise said PV devices, and, the basic process for the stepwise fabrication of silicon nanowire arrays (SiNWs) for PV or other device applications. The method for producing SiNW arrays on partially anodized Al or Al layers adhered to other material structures is presented, in addition to techniques for integrating the engineered SiNW arrays into PV device designs. Practitioners of ordinary skill in the art will readily recognize that the methods and designs described herein can be extended to starting materials other than Al, active opto-electronic nano-structures made from materials other than Si, and devices that utilize metallic and semiconducting nanoscale structures for fabrication and function other than photovoltaics. In this patent, the term nano (nanowire, nanoscale, nanopores, etc.) refers to a material structure(s) having, utilizing, incorporating, or otherwise manifesting a characteristic length scale of 1-1000 nm, either in form or function, in one or more relevant spatial dimensions (directions).

In one preferred embodiment, the invention features a method to fabricate an opto-electronic device that operates by utilizing semiconducting nanowire arrays as the active components.

### Substrate Preparation-Anodization of Aluminum

An aluminum (99.8% pure or greater) component (foil, sheet, thread, coated substrate, or other geometry) is first electro-polished in a solution of 4:1 ethyl alcohol (95%): perchloric acid (ACS, 60-62%) at a temperature below 5° C., the Al is anodically biased at 10 volts for three minutes with a current limit of 2 amps to obtain a bright, smooth Al surface. In both the electro-polishing and anodization steps it is vital to have the cathode (counter-electrode) geometry be symmetric with the anode to achieve a uniform surface. The symmetry assures a uniform electric field configuration over the entire surface of the structure being anodized. Thus, in the case of an Al thread, the cathode would be a cylinder with the anode thread at the center, while in the case of a planar substrate the cathode too would have planar symmetry. The symmetry ensures a uniform electric field distribution on the anode surface, and hence, uniform electro-polishing (or anodization). The cathodes used here are typically a stainless steel mesh. After electro-polishing, the Al (substrate) is rinsed in de-ionized water and then anodically anodized in an acidic electrolyte (sulfuric, oxalic, glycolic, phosphoric, malonic, tartaric, malic, citric or other). Prior to anodization (and electro-polishing) the electrolyte/air interface of the Al component is masked with a polymer (Coscoat® General Chemical) to prevent electro-chemical breakdown at the interface. By varying the type and concentration of the electrolyte, the bath temperature, and the anodization voltage, nano-porous Al₂O₃ can be formed with pore diameters ranging from 2-900 nm on a 35-980 nm pitch. In the preferred embodiment, a 1 mm diameter Al (99.999%) thread (wire) is anodized in a 3M solution of malonic acid at 5° C. and 130 Volts. The anodization is performed using a computer controlled bi-polar power supply. The anodization is first performed in a constant voltage (CV) mode while monitoring the current. The current starts low and begins to rise as oxidation occurs and alumina pores nucleate over the aluminum surface. Islands of porous AAO begin to nucleate randomly about the Al surface and percolate along the length laterally until the entire surface is covered by this porous network. The current slowly increases at constant voltage (CV), which is indicative of the progression of the island growth. Once the current begins to plateau, this indicates the complete conversion of the Al metal surface to a porous AAO layer covering the underlying metal: a steady state. At this point, a controlled transition is made to a constant current (CC) regime (at the plateau level) where the AAO thickness (pore depth) increases with continued applied current: as the diameter and spacing of the pores has been set. The anodization is then continued until the pores reach their desired depth (1-100 μm). Then, the anodization is switched back to CV mode and the voltage is lowered in sequential steps of 1-10 volts at 1-5 minute intervals so that successively smaller nanofinger protuberances extend from the bottom of the pores into the oxide barrier layer. This “step-down” anodization technique is characterized by a current drop-rise-plateau sequence at each successive step, which thins the AAO barrier layer that develops at the anodization front. A further voltage blast (increase to the original anodization voltage (130 volts for malonic acid here)) for 1 minute is sometimes used after the step down process to disrupt the integrity of the remaining AAO barrier layer and make the subsequent pore widening process more effective in removing the barrier entirely. Etching the AAO in a 5 wt % phosphoric acid solution (37° C.) both widens (increases) the diameter of the pores and fully opens them at the bottom such that the Al at the Al/AAO interface can be accessed for the next step in the NW production process. While the barrier layer can be removed, a thin (4 nm) native oxide layer forms on Al surfaces in 100 ps when exposed to air. Another technique for thinning the barrier layer involves switching the anodization bath and voltage to a schedule that creates much smaller pores at the growth front (for malonic acid (2M, 130 V) above is switched to 0.3 weight % oxalic acid at a voltage of 20-40 V for 1-10 minutes), again followed a phosphoric acid pore widening/barrier removal step. At this point the Al/AAO thread substrate is thoroughly rinsed in de-ionized water to remove any remnant process chemicals and then dried in air such that it is now ready for SiNW growth.

In another embodiment, the anodization process used 3 M malonic acid at a temperature of 5° C. with 6-6 V steps until the process reached about 80 V and then 6-3 V steps until the process reached about 60 V. The process ran for 49 minutes and 35 seconds. The sample was then pore widened in a solution of H3PO4 at a temperature of 37° C. for 23 minutes.

### Nanowire Growth

A chemical vapor deposition (CVD) reactor is used to grow SiNWs on the anodized Aluminum. VLS SiNW growth is typically carried out in a low pressure (˜10-500 Torr), isothermal quartz tube reactor at 550-650° C. using SiH₄ (10% in H₂) as the silicon source. In the preferred embodiment, the flow rate in the CVD reactor is 100 sccm, 90 sccm silane (10% SiH₄ in H₂), with a reactor pressure of 38 Ton, and a temperature of 600° C. NWs grown under these conditions are predominantly single crystal with growth directions of <110>, <111> or <112> due to random nucleation of Si within the AAO pores. At proper pressures and proper temperatures, the SiH₄ diffuses into the pores and preferentially decomposes on the catalytic surface at the bottom of the pore, rather than the surface or walls of the pores. Higher growth temperatures or reduced hydrogen fraction in the reactor gas mix lead to an increased rate of silicon thin film deposition compared to VLS growth. The parameter space of temperature, pressure, flow rate, and relative gas concentrations covers many possible scenarios which can produce a multitude of acceptable results depending on the nature of the substrate, catalyst, and the desired outcome. The parameters delineated for this embodiment are preferred for the Al/AAO thread or planar substrate described in the previous section. As Si decomposes from the silane molecules, a stable liquid alloy phase (Si/Al eutectic) forms and when the Si concentration in the melt reaches a critical level, a SiNW crystalline phase forms. Since the only unconstrained special direction is the vector beginning at the pore base and going up normal to the surface of the substrate, the crystal forms at the Al/AAO interface and as the process continues, the eutectic grows out on the NW tip eventually emerging through the outer opening of the AAO pore. This phase is the Al—Si eutectic which forms at ˜577° C. The SiNWs nucleate in the bottom of the AAO pores and then emerge beyond the pore boundary and continue to grow in free space while retaining the AAO pore diameter under the appropriate conditions. An Al—Si melt resides on the tip of the nanowire at the growth front and provides a means for continued growth as long as Si is continually replenished in the melt from the vapor phase. Since some of the Al is incorporated into the silicon lattice, as the growth continues, eventually it will be consumed, thus terminating the NW growth process. By adjusting the diameter and depth of the AAO pores, in addition to the thickness or presence of an AAO barrier layer at the base, the eutectic phase system can be mass (size) tuned to control the amount of Al that emerges through the pore by adjusting the size of the Si—Al eutectic phase on the NW growth front by also employing systematic control of the CVD parameter settings used in the SiNW growth process. In one embodiment, SiNWs can nucleate even with a substantial (10-200 nm thick) barrier layer present at the base of the AAO pores. This CVD (VLS) process yields SiNWs emanating from the Al metal (in Ohmic contact) that grow up through the AAO pores and extend into free space, while retaining the pore diameter (100-250 nm), with a length of 1-500 μm (preferably 10-30). The growth of SiNWs using an Al catalyst as described above produce SiNWs with an Al concentration of ˜1-5×10¹⁹/cm³. The relatively high level of dopant is advantageous for the fabrication of radial p-n junction SiNW devices which require a highly doped wire core to reduce series resistance. The high doping also reduces the minority carrier diffusion length, which is problematic for devices such as wafer PV systems that have characteristic carrier extraction distances of 100 μm, however, for the radial geometry presented here, the radial carrier extraction distance is orders of magnitude less, which allows for the high doping profile while still having a high carrier extraction percentage over the characteristic distances of this system (100 nm).

The NW growth process described above can yield discrete SiNWs in an array such that a silicon nanowire emanates from a single pore, and ideally, there is a 1 to 1 correspondence of NWs to the pores. In this case, the NWs are electrically connected in a parallel circuit through the Al metal from which the NWs nucleated. While there exists a certain surface area fraction of the outer AAO periphery that will have no p-type silicon directly on it, the effective surface area of the NWs is still 2-1000 times greater than the “footprint” surface area of the AAO due to the high aspect ratio of the NWs. Further, the NWs are not completely straight and the non-linearity effectively ensures that 100% of the incident radiation (even before n, or i-n-type coating) will strike the Si before the AAO surface.

Nonetheless, in another embodiment, a p-type film (which would now require a dopant input in the source gas, such as Boron) can be deposited intentionally to ensure that every surface of the AAO has a p-type coating which would further add electrical continuity to the outer surface of the structure (film-linked nanowires).

In another embodiment, an intrinsic silicon layer is applied over the p-type (in either the discreet NW configuration or the continuous film-linked scenario) to form the foundation for creating numerous p-i-n junctions once an n-type layer is applied.

### Formation of p-n Junctions

A conformal n-type silicon film is deposited after VLS growth of the p-type NWs to engineer a complete functional array of p-n (or p-i-n) diode junctions (optionally an intrinsic silicon layer can be deposited after nanowire growth) on the periphery of the thread ar planar substrate. Preferably, the n-type silicon layer is deposited by CVD on the outer surface of the p-type NWs in the reactor (in-situ) immediately after VLS growth without exposing the material to air. If an intrinsic layer or additional p-type coating is applied prior to the n-type layer, it is also preferred to perform these procedures without breaking the seal (vacuum) on the CVD system.

This is desirable to avoid the oxidation of the SiNW surfaces, since the presence of an oxide layer on the NW surface residing between the p and n layers would diminish device performance by creating interface states that can lead to carrier recombination. Eliminating an oxide layer after it's formation would require an oxide removal step by either a chemical etch (BOE), plasma removal, or other oxide removal method prior to the n- (1-n-) type coating. While the dangling atomic Si bonds (surface states) on the NW surfaces can be passivated with hydrogen using an in-situ treatment or by oxide etching in BOE under proper conditions. This can protect the surface for a while if performed prior to air (oxygen/oxidation) exposure.

The in-situ n-type deposition is accomplished by introducing a short pause after VLS growth of the p-type SiNWs during which SiH₄ will be switched out of the reactor using a nitrogen (or other inert gas) purge and then n-type silicon thin films are grown using systematically determined (10⁻³ to 10⁻⁴) PH₃/SiH₄ dopant levels to achieve the desired doping. The reactor temperature is set at 600° C. to 650° C. for this step. Consequently, by adjusting growth conditions it is possible to switch between the regimes where NW growth is dominant to one that is dominated by thin film deposition. The n-type Si shell is polycrystalline at these deposition temperatures but exhibits a uniform thickness along the length of the nanowires. However, in another embodiment di-silane (Si₂H₆) is substituted for silane which can yield epitaxial n-type films at lower temperatures. It should be noted that during the n-type thin film coating process, the Si coats virtually all of the surfaces in the CVD reactor, and thus; appropriate measures must be taken to protect or otherwise expose (or later remove the n-type coating selectively) certain selected regions of the surfaces after deposition, particularly certain electrical contacts on the substrate, that will later be used in a device such as a photovoltaic device. A masking agent can be used to facilitate the protection/clearing of surfaces to retain their pre-CVD morphology, structure and physical nature. In the preferred embodiment the entire excess Al (on the nanowire tips) is consumed in the NW growth process, however, in the event that excess Al needs to be removed from the NW tips or otherwise, it is possible to achieve this too, in-situ, by introducing an HCL gas mix to etch the Al during an etch purge schedule. It is also possible to raise the reactor temperature to evaporate excess Al from the NW tips.

The use of various coating technologies, especially CVD, to produce a photovoltaic device requires that the various electrically distinct layers not be inadvertently shorted together. In this case, masking techniques are devised that restrict the application of the coating in order to maintain appropriate electrical isolation. However, one of ordinary skill will recognize that etching techniques may be used to remove unwanted coatings so as to maintain electrical contacts that are electrically isolated from the coatings and any other parts of the device that require discreet continuity.

Techniques to restrict the n-type coating from surface areas on the substrate where it is unwanted include a post-process removal using a chemical etch, a mechanical removal (sanding, abrasion, reactive ion etch), masking, or making the substrate of adequate size such that it has an intentional sacrificial border, appropriately located, that is broken off, cut, etched, or otherwise removed after the final CVD coating is complete. In another embodiment, planar substrates are inspected after the device is formed to locate sections that have complete coverage with the SiNW and then cutting out these sections that are then assembled into a complete PV device.

In another embodiment, a p-type silicon layer is coated onto the p-type nanowires. Where there are pores in the AAO unoccupied by SiNW or other defects that would provide a short circuit to the substrate, the p-type layer coats the pore and/or defect and isolates the substrate underneath from the n-type layer that is coated on top. In another embodiment, an insulating layer can be coated onto the device, and then the insulating layer selectively etched from regions where there are no pin-holes in the AAO layer. Regions of the substrate where it is typical to have missing SiNW can be masked so that the anodization process does not produce pores in those regions. These may be along the edges of the substrate. In yet another embodiment, the finished substrate is inspected to detect regions where there are defects or missing SiNR, and hence short circuits. In this embodiment, absorption characteristics of the nanowires may be used to use opto-electronic detectors to detect the presence or absence of nano-wires.

Plasma-Enhanced CVD (PE-CVD) techniques can also be used for SiNW growth or coating process to achieve similar results at reduced temperatures and other relevant parameters.

### PV Device Completion

To complete the formation of a PV device (in this embodiment a PV thread) an outer conductive coating (cathode) must be applied over the n-type layer. The ideal cathode would transmit 100% of the incident light while providing high electrical conductivity (like that of a metal). Thus, there are various options for a transparent conductor. H.C. Stark makes a product, Clevios 1000® that is a PEDOT suspension in liquid that can be spray or dip applied and has up to 90% transmission in the solar band with a sheet resistance of ˜100 Ohms pre square. Similarly, Eikos provides Invisicon® product that is a carbon nanotube suspension that can also be applied by spray or dip coating. The spray or dip coating techniques are attractive from a cost and ease of application perspective, however, there are limitations to the uniformity of the coating and the ability to apply it such that all the nanometer scale nooks and cranny's between the SiNWs get fully electrically coated with the material. Another method to apply the cathode conductor that shows greater promise for a uniform coating is a CVD application, such as a PEDOT coating developed by GVD Inc. However it is applied, the coating must provide sufficient conductivity and transparency for the maximum function of the PV device. A lack of electrical conductivity can be compensated by using a cathode bus conductor that would intersect the transparent cathode periodically to provide an “effective conductivity” close to that of the Al metal anode structure. A helical wind of fine copper or aluminum wire is used in the case of the current PV thread embodiment. Planar embodiments may have Aluminum evaporated in a mesh other pattern onto the transparent conductor. After the transparent conductive coating is applied, a transparent environmentally protective layer is applied to the surface to complete the device. This material can be a silicon based resin, Teflon™, parylene, polyimide, or other robust, transparent, inert, non-conductive layer that is flexible and resilient to environmental (UV) degradation.

In the preferred embodiment, spools of Al metal thread will be anodized, pore widened, entered into a CVD reactor using a reel-to-reel process, have the nanowires produced and coating of opposite doping to the NWs applied in one step, removed, coated with an electrode (cathode), possibly using a CVD process, and followed with a protective polymer. In the reel-to-reel, the thread may be oriented vertically in going through the reactor to minimized strain and deformation of the material when exposed to the temperatures and process strains inherent to a reel-to-reel process.

While the above embodiment describes the method for fabrication SiNW arrays on a partially anodized Al thread, one of ordinary skill will realize the same general procedure applies to another geometrical form of Al metal, or a layer of Al metal thick enough (1-2 microns) to form an AAO layer on the Al metal with enough Al metal present at the bottom of the AAO pores to adequately nucleate the SiNWs and still leave a sufficient conducting layer of Al metal to use as the anode of a opto-electronic device. In one embodiment, a borosilicate glass slide is used, coated with Al, that is partially anodized and then Si nanowires grown with a remnant layer of Al sufficient for electrical contact. In this embodiment, the nanowires may be grown in 5 minutes. The reactor parameters may be silane at 50 sccm in a reactor with a temperature of 600 C and a pressure of 38 Torr.

In the glass substrate embodiment, a layer of Al (1-20 microns thick) is deposited on the surface by e-beam, thermal, or sputter coating evaporation methods, electro-plating, physical cladding or other technique. The glass can have another conductive layer (ITO, metal etc.) on its surface prior to al coating to provide additional conductivity or other electrical function. The Al is then partially anodized using the AAO production techniques spelled out previously above such that a layer of porous AAO is produced on the Al metal with a sufficient amount of Al metal retained under the AAO to function both as an electrical conductor and a catalyst for SiNW growth using the VLS technique. The basic process for porous AAO layer formation and SiNW growth follows the same basic outline above. Depending on the desired pore diameter and center-to-center spacing, the proper electrolyte type, concentration and anodization voltage is used. A step-down, or electrolytic alteration technique is used to disrupt the integrity or the AAO barrier layer that forms at the pore bases so it can be partially or fully removed using a phosphoric (or other) acid etch. Then a similar CVD process is employed to grow the NWs using the Al as a catalyst for the VLS process.

As mentioned above, when depositing Si films or coatings, the material will coat most any surface in the reactor. This can lead to the necessity to mask off certain areas of the substrate to later access a conductive surface and make contact to it as the device anode or cathode. Further in a layered geometry (Al/AAO/glass for example) the conductive (doped) Si coating may make electrical contact with the Al layer and short the anode and cathode of the device. Thus sacrificial edges that are removed after full electrical contact fabrication may be employed or masking techniques can be utilized. In a SiNW array grown on a metallic thread or wire geometry, there are no edges and electrical shorts can be avoided by continuously feeding wire stock into the reaction chamber. In this embodiment, the ends of the thread are kept out of the reactor, eliminating some or all of the “full-coating” issue associated with the n-type deposition. Alternatively pieces of thread can be fully coated and the ends trimmed mechanically or chemically to expose the anode (cathode) for electrical contact. A similar technique is used with foils. The edges of the foil can be insulated by preparing a non-porous aluminum oxide layer around the edges of the foil to prevent SiNW nucleation and eliminate any exposed edges of conducting material. Another option in the foil instance is to trim the edges after full anode, SiNR, diode junction formation, and final electrode deposition to eliminate any possible short circuiting.

In another embodiment, the nanowires will nucleate off the Al even without a pore widening etch, i.e., the AAO barrier layer is still at the bottom of the pores, yet the nanowires grow. Further, hydrogen can be introduced into the reactor to reduce the AAO into Al metal and thin the barrier layer some by reducing the AAO.

In another embodiment, the temperature of the reactor during deposition of the n-type material is lowered to be well below the melting point of Aluminum. For example, the melting point of Aluminum is 660° C. Therefore, the CVD temperature can be lowered to approximately 650 degrees, whereby silane, hydrogen and phosphine as a dopant cause an n-type layer to coat the device (SiNWs). Temperatures as low as approximately 550 degrees may be used to produce the SiNWs. It is also recognized that other gases commonly used in silicon deposition such as di-silane or silicon tetra-chloride could be used to obtain a conformal n-type layer epitaxially or polycrystalline in structures at temperatures below the melting point of Al.

In another embodiment the SiNWs are produced by the Vapor-Solid-Solid (VSS) mechanism at temperatures below the eutectic temperature as opposed to VLS technique.

In another embodiment the SiNWs are produced at still lower temperatures using the plasma enhanced chemical vapor deposition (PECVD) process.

The fabrication method disclosed here is different than many VLS approaches to templated SiNW growths, which typically use gold catalytic seeds that are electrochemically deposited into commercially obtained AAO membranes. In this invention, the Al metal underlying the AAO is used as the catalyst. Thus, every pore has a catalyst and SiNWs grow copiously. The SiNWs grown by this process nucleate at the Al-AAO interface, via the formation of an Al—Si eutectic phase, and grow up and out of the AAO pores while retaining the diameter. The SiNWs contain 1018/cm3 to 1020/cm3 of Al as a p-type dopant source, thus, the Al catalyst self-dopes the NWs without the need to add additional dopant gas sources, and, they are in Ohmic contact with the Al metal. The remnant Al layer is used as the anode of the PV device. At the final stage of SiNW growth, the reactor conditions are adjusted to produce a thin-film layer covering the AAO surface and connecting the NWs. The thin film maximizes the photo-active surface area and adds a level of manufacturing redundancy: filling any unintended pinholes in the AAO layer prior to n-type coating to prevent short-circuiting. A material such as p-silicon can be used.

Using optimized substrates and appropriate CVD reactor conditions (that are detailed in the work pan), the Al that emerges from the AAO pore in the eutectic phase on the SiNW growth front is consumed as dopant during the SiNW growth process. Thus, a conformal n-type silicon film will be deposited in-situ immediately after VLS growth of the p-type NWs. This will be accomplished by introducing a short growth pause after VLS growth of the p-type SiNWs during which SiH4 will be switched out of the reactor and the reactor temperature will be increased. Higher growth temperatures lead to an increased rate of silicon thin film deposition. Consequently, by adjusting growth conditions it is possible to switch between the regimes where NW growth is dominant to one that is dominated by thin film deposition. The n-type Si shell is polycrystalline at these deposition temperatures but exhibits a uniform thickness along the length of the wires.

Finally, to complete the manufacture of the functional nanomaterial, a conformal transparent conductive coating (TCC) must be applied over the n-type layer to act as the cathode. There are many options for a TCC, however, the initial approach uses a flexible conductive PEDOT (polyethylene-3,4-dioxythiophene) coating applied using GVD Corporation's Oxidative Chemical Vapor Deposition (oCVD) technology. The oCVD process is an innovative, all-dry, low temperature method for forming intrinsically-conductive polymer coatings on a range of substrates. oCVD “shrink-wraps” high-surface-area substrates like nanowires with a conformal, high transmittance, electrically-conductive polymer coating. The coatings are chemically pure, mechanically-flexible and intrinsically-conductive. It should be noted that the schematic shows the TCC full filling all voids up to the height of the nanowires. The more realistic scenario, shown in the SEM micrograph shows the PEDOT coating (rough texture) to be continuous and conformal to the outer surface of the NWs. The final device will also have an environmentally protective transparent layer over the TCC. Thus, the TCC is required to be conformal and continuous to be an effective anode, however, any gaps left will either be filled or covered by the environmental coating and should not be of consequence to device performance.

The described embodiments of the invention are intended to be exemplary and numerous variations and modifications will be apparent to those skilled in the art. All such variations and modifications are intended to be within the scope of the present invention as defined in the appended claims. Although the present invention has been described and illustrated in detail, it is to be clearly understood that the same is by way of illustration and example only, and is not to be taken by way of limitation. It is appreciated that various features of the invention which are, for clarity, described in the context of separate embodiments may also be provided in combination in a single embodiment. Conversely, various features of the invention which are, for brevity, described in the context of a single embodiment may also be provided separately or in any suitable combination. It is appreciated that the particular embodiment described in the specification or figures is intended only to provide an extremely detailed disclosure of the present invention and is not intended to be limiting. The spirit and scope of the present invention are to be limited only by the terms of the appended claims.

What is claimed:

1. A silicon nanowire device comprising:
A substrate with a surface and an anodized metallic layer adjacent to the substrate at the surface, said anodized metallic layer having an outer surface opposite from the substrate surface;
A plurality of silicon nanowires of a first charge carrier type, where a first end of each of the plurality of silicon nanowires is attached to the substrate and the second end extends at least to the outer surface of the anodized layer;
A layer of silicon of a second charge carrier type covering the second ends of the plurality of nanowires, whereby said layer does not have a direct electrical connection with the substrate.

2. The device of claim 1 where the silicon nanowires are doped with Aluminum.

3. The device of claim 1 where the anodized layer is anodized aluminum.

4. The device of claim 1 where the substrate is Aluminum.

5. The device of claim 1 where the silicon nanowires are doped with Aluminum, the anodized layer is anodized aluminum and the substrate is aluminum.

6. The device of claim 1 where the silicon nanowires protrude past the opposing surface of the anodized layer.

7. A method of forming a plurality of silicon nanowires comprising:
Growing silicon nanowires using a VLS process through a plurality of pores of an anodized aluminum layer adjacent to an aluminum layer where the aluminum at the bottom of the anodized aluminum pores is the catalyst; and
Coating the silicon nanowires with an N-type semiconductor.

8. The method of claim 7 further comprising:
Anodizing an aluminum layer such that the anodization stops prior to a plurality of the pores formed by the anodization from reaching the surface of the substrate.

9. The method of claim 7 further comprising:
Masking off a predetermined region of the aluminum layer by forming an alumina layer that does not have pores in it in the pre-determined region.

10. The method of claim 7 further comprising preventing the n-type layer from being in electrical contact with the substrate.

11. The method of claim 7 further comprising continuing the VLS process until the aluminum constituting the catalyst is consumed as the dopant of the silicon nanowire.

12. A method of forming a silicon nanowire device comprising:
Anodizing an aluminum layer to produce a plurality of pores extending from the outer surface of the anodized layer to a location in an interface region at the bottom surface of the anodized layer such that a portion of aluminum remains at the bottom of the pores;
Growing silicon nanowires using the VLS process whereby the aluminum remaining at the bottom of the pores is used as the catalyst at the eutectic tip and as the dopant of the silicon nanowire.

13. The method of claim 12 further comprising continuing the silicon nanowire growth until the aluminum catalyst at the eutectic tip is consumed as dopant of the silicon nanowire.

14. The method of claim 12 further comprising, removing the eutectic tips of the plurality of silicon nanowires in order to remove the remaining catalyst.

15. The method of claim 10 further comprising coating the device with a passivating film in order to prevent a short circuit from the N-type layer to the substrate through any pores that do not have silicon nanowires growing through them.

16. The method of claim 7 further comprising coating the nanowires with an intrinsic silicon layer prior to coating with the N type silicon layer.

17. The method of claim 7 further comprising coating the nanowires with a P-type silicon layer prior to coating with the N type silicon layer.

18. The method of claim 7 further comprising etching the N-type silicon layer from a predetermined region of the anodized aluminum surface.

19. The device of claim 1 further comprising a layer of a transparent conductor, operatively in contact with the N-type silicon layer.

20. The device of claim 19 further comprising a metallic conducting wire operatively in contact with the transparent conductor layer.
